(19) United States
(12) Patent Application Publication
(10) Pub. No.: US 2006/0077638 A1
(43) Pub. Date: Apr. 13, 2006

(54) Adaptive interface using flexible fingers

(76) Inventor: Peter C. Salmon, Mountain View, CA (US)

Correspondence Address: Aldo J. Test;DORSEY & WHITNEY LLP, Suite 3400, 4 Embarcadero, San Francisco, CA, 94111, US

(21) Appl. No.: 10/997,566

(22) Filed: Nov. 24, 2004

Related U.S. Application Data
(60) Provisional application No. 60/617,727, filed on Oct. 12, 2004.

(51) Int. Cl. H05K 7/20

(52) U.S. Cl. 361/704; 361/707

(57) ABSTRACT

A multi-function interface adaptor comprises a base layer and flexible fingers extending from it. The interface adaptor is interposed between two objects to provide a mechanical and/or thermal interface with stress relief or shock absorption. Using bent fingers operating like springs, shocks and distributed stresses can be relieved in the plane of the adaptor, as well as normal to the plane. A preferred embodiment is an Interface Adaptor that replaces thermal grease between a semiconductor chip and its associated heat sink.

### RELATED APPLICATIONS

This application claims priority to Provisional Application Ser. No. 60/617,727 filed Oct. 12, 2004.

### THE INVENTION

This invention relates to interfaces between components having dissimilar thermal or mechanical properties, and more particularly to multi-function adaptive interfaces that efficiently dissipate heat and relieve thermal and mechanical stresses between bonded components.

### BACKGROUND OF THE INVENTION

The process of fabricating or assembling complex components by laminating multiple layers is well known. Each layer may contribute different properties or benefits to the whole: these may include structural strength, electrical conductivity, thermal conductivity, stress relief, shock absorption, planarization, dielectric properties, and sensing properties such as found in thermocouple sensors and strain sensors.

As a practical matter, layers chosen for their special properties may not be ideally suited for direct lamination. They may have dissimilar expansion characteristics for example, which could lead to cracking or de-lamination when the overall component is subjected to temperature changes. A stress-relieving layer may overcome this type of problem. In addition, it is often desirable to provide a low impedance thermal path between laminated layers, to assist in cooling the overall component.

An interface of particular interest is the interface between a semiconductor chip and its associated heat sink. Heat sinks are typically fabricated from metals that are good heat conductors and also typically expand and contract at faster rates than semi-conductor materials such as silicon. For example, copper has a coefficient of thermal expansion (CTE) of 17 parts per million (ppm) per degree Centigrade (° C.), while silicon has a CTE of approximately 3 ppm/° C. This means that if an integrated circuit (IC) chip is directly attached to a copper member, large stresses will be induced during the temperature cycles of manufacture and operation. These stresses may cause cracking/failure of the chips, performance degradation, or de-lamination. Current solutions to this problem typically include a thin layer of thermal grease between the chip and the heat sink. This layer conducts heat and also allows relative motion between the surfaces to relieve mechanical stresses induced by the thermal gradients (“thermal stress”). A preferred embodiment of the current invention replaces the thermal grease with a new device called herein an “Interface Adaptor”. The Interface Adaptor is intended to have superior thermal conductivity while providing a similar or improved level of stress relief.

Semiconductor devices such as microprocessor chips operate at high power levels, in excess of 100 watts (W) for recent devices. The International Technology Roadmap for Semiconductors (ITRS) projects that this power will increase to 465 W by 2010. This power is consumed by the transistors that implement the microprocessor functions; it appears as heat generated at their junctions. The total power is summed over all of the transistors: some of them are active for switching capacitive loads, and some of them are inactive but draw a small leakage current.

It is desirable to limit the maximum junction temperature, to provide long life and good reliability of the semiconductor devices. The ITRS provides a desired maximum of 85° C. in 2010 at an ambient temperature of 45° C., providing “thermal headroom” of only 40° C. Achieving this level of cooling requires thermal paths between chip and heat sink having very low thermal impedance. Alternatively, the problem can be cast as a requirement for high thermal conductivity between chip and heat sink. Solutions have been so intractable that the ITRS has characterized the problem as having “no known manufacturable solution”.

Active foils have recently become available; they are typically used to bond metal surfaces together. One such foil consists of micro-layers of nickel and aluminum. Generating a spark at an edge of the foil activates a chemical reaction that releases heat. The heat can be used to melt one or more layers of solder material stacked between the surfaces to be bonded, along with the active foil. This method is reported to achieve excellent thermal and mechanical bonds, and eliminates the need for a solder reflow oven.

There is a parallel between the interfacing problems confronted on the front and the back sides of an IC chip; in each case the chip typically has a lower CTE than the things it interfaces with. The problem at the front side is illustrated by flip chip packages. The most common flip chip attachment structure is typically quite rigid, employing solder balls to connect between terminals on the chip and the substrate. A common substrate material is glass-epoxy laminate with a CTE of 17 ppm/° C., the same as copper. If an epoxy under-layer is not employed to strengthen the joint, the maximum silicon chip size that can currently be flip chip bonded using this structure is 3 mm on a side. Larger chips require an epoxy glue layer to hold things together and prevent cracking, and the glue layer creates problems in rework. Rework is the procedure used to replace an already assembled chip that proves to be defective. Usually rework is not attempted if an epoxy under layer has been used, and this can lead to high reject costs. Since a typical microprocessor has an edge dimension of 18 mm a new type of flip chip connector is required for this larger chip size, if an epoxy under layer is to be avoided. The flip chip connections described herein employ copper mesas that act like flexural beams to overcome this problem. This flip chip structure is described in the author's co-pending application, “Fine Pitch Electronic Socket for Temporary or Permanent Attachments”.

On the back side of the chip, similar problems must be resolved. Thermal grease has been used as a popular solution to this problem, wherein the grease allows the mating parts to slide, to relieve induced shear stresses. However, the resulting thermal joint has a calculated thermal resistance of 0.1° C./W. The calculation assumes a chip area of 310 mm², chip thickness of 100 μm, and thermal grease thickness of 0.003 inches (Arctic Silver Premium Thermal Compound). The temperature drop across this interface is 50° C. at 500 W, exceeding the available headroom of 40° C. Thus a new solution is required on the back side of the chip as well as on the front side. The solution should provide the necessary stress relief while also meeting the projected demands for power dissipation and thermal headroom.

New manufacturing processes are currently under development for fabricating components using printed layers. This fabrication technique has been referred to as “printed electronics”. The printed layers typically contain positive material which may include metal powders, ceramic powders, or polymers, applied as printing inks. The positive materials are embedded in negative material. The powdered materials are sintered to create solids, and the negative material is burned off or otherwise removed. Complex three-dimensional components can be fabricated by layering suitable materials in this manner. The complex components may include arbitrary angles that would be difficult to manufacture using other existing fabrication methods such as stamping, milling, or drilling. Accordingly, this capability enables the fabrication of bent elements or springs, as in a preferred embodiment of the current invention.

The first preferred embodiment of the current invention employs wafer level processing to fabricate an adaptive interface layer directly on the back side of a semiconductor wafer. Fabrication costs are reduced by integrating the necessary manufacturing steps with back-end wafer processes, due to parallel processing. For example, a typical microprocessor chip may measure 80×80 millimeters, resulting in 177 die on a 300 millimeter wafer. In this case the additional wafer fabrication steps would be amortized over around 159 die, assuming 90% yield.

### SUMMARY OF THE INVENTION

The current invention is an Interface Adaptor that includes a base layer and flexible fingers extending from the base layer. It is typically interposed between two objects to ease mechanical and/or thermal stresses that would otherwise occur at the joint. It may also be used as a shock absorber.

A preferred embodiment of the current invention is an Interface Adaptor that provides good thermal coupling between a metal heat sink and a silicon chip. A popular choice for heat sink material is copper because it is an excellent conductor of heat. In principle the Interface Adaptor can be made of any thermally conductive material, but preferably it is made of the same or a similar material as the heat sink, to minimize thermal stress problems at the interface between them. The Interface Adaptor has a base that can be bonded to the heat sink using solder or active foils for example. Extending from the base are copper fingers that provide a good thermal path between the base and the chip. Typically 25%-75% of the cross-sectional area in the finger section will be occupied by copper, providing a thermal conductivity between one and three fourths that of solid copper. However, because the fingers are disjoint and are separated by air or another medium, they can flex to relieve thermal stress. The degree of flexibility in the horizontal plane (x, y coordinates) will depend on the width and length of the fingers. In principle, the thermal stress of an arbitrarily large chip operating over an arbitrarily large temperature range can be relieved by making the fingers long enough and thin enough.

By creating a bend in a finger, its length can more easily adjust to relieve applied tensile or compressive forces. In turn, this will act to relieve any normal component of stress in the adjacent laminated layers. Accordingly, a preferred embodiment of the current invention includes one or more bends in each finger, to create the behavior of a spring. This construction enables stress relief in the z-direction, as well as in the −x and −y directions.

The fingers are formed in an array, and each finger acts like an independent spring. Typically, mechanical stresses and thermal stresses (like hot spots) will be distributed over areas that are large compared with the footprint of a single finger. Thus, the fingers represent a fine-grained construction for collectively relieving stresses occurring over relatively larger spatial dimensions.

A process for fabricating an Interface Adaptor on the back side of a semiconductor wafer is described. Spin-on layers of negative photo resist are exposed in sequence to create a staircase pattern of cross-linked resist. After the unexposed resist is removed in developer, electroformed copper is built up in the spaces to form flexible springs. After planarizing using a chemical mechanical polishing (CMP) process, the cross-linked resist is removed in a stripping solution.

### BRIEF DESCRIPTION OF THE DRAWINGS

The foregoing and other objects of the invention will be more clearly understood from the accompanying drawings and description of the invention:

FIG. 1A is a cross-sectional side view of a fragment of an Interface Adaptor of the current invention;

FIG. 1B is a bottom view of the fragment of FIG. 1A;

FIG. 1C is a cross-sectional view of a fragment of an Interface Adaptor having two base layers;

FIG. 2 is a cross-sectional view showing a preferred stackup of layers between a printed circuit board and an IC chip, and between the IC chip and its heat sink;

FIG. 3 is a cross-sectional schematic view of an electroplating cell used to plate the connections between the fingers of an Interface Adaptor and the back of a semiconductor wafer;

FIG. 4 is a cross-sectional view of a solder joint between a copper finger and a semiconductor wafer;

FIG. 5A-5I depicts in cross-section a series of process steps for fabricating an Interface Adaptor on the back side of a semiconductor wafer;

FIG. 6A is a cross-sectional view of an IC chip having an integrated Interface Adaptor;

FIG. 6B is an expanded cross-sectional view of the finger attachment area of FIG. 6A; and

FIG. 6C is an expanded cross-sectional view of the finger attachment area, including an electrical isolation layer.

### DETAILED DESCRIPTION OF THE PREFERRED EMBODIMENTS

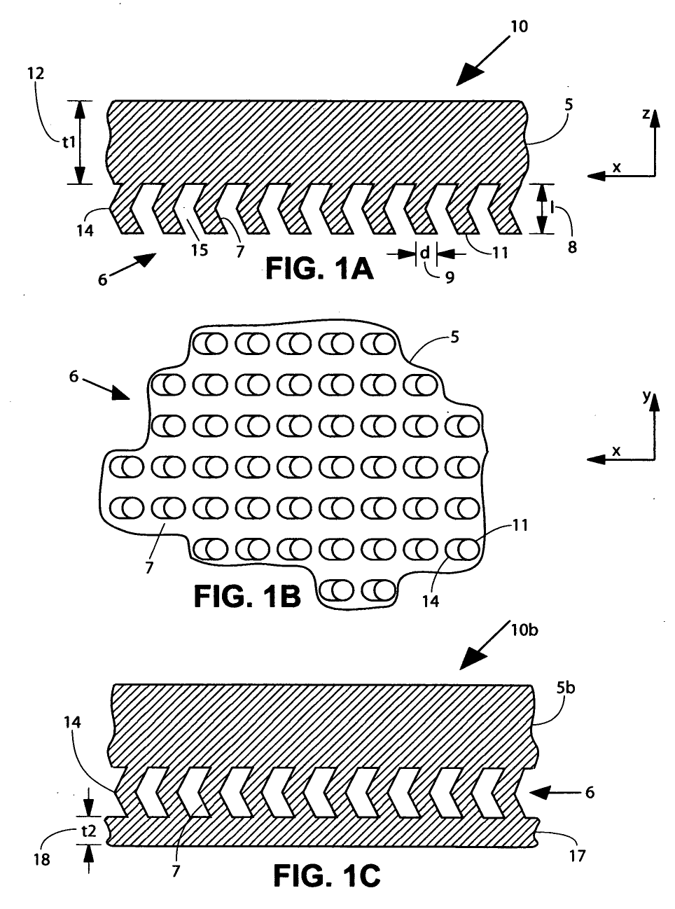

FIG. 1A shows a fragment of an Interface Adaptor 10 of the current invention in cross-section, including a base layer 5 and an array 6 of fingers 7. By virtue of its length, 1, 8 and its diameter, d, 9, each finger 7 has flexibility that allows its end 11 to move in the −x and −y directions relative to base layer 5. Base layer 5 is preferably a planar element defined in the −x and −y directions, and having a thickness, t1, t2. Each finger 7 also preferably has a bend 14 in it, providing flexibility in the −z direction, normal to base layer 5. The bend in each finger enables it to operate like a spring, particularly with regard to expansion/contraction in the −z direction. Because of gaps 15 between fingers 7, each finger can move independently of its neighbors. The fact that each finger acts flexibly and independently enables a collective behavior for the array 6 of fingers, wherein localized stresses between Interface Adaptor 10 and an attached object or component can be relieved in the −x, −y, and −z dimensions. In some applications, a set of springs will be all that is required at the interface; in this case a substantive base layer such as 5 is not necessary and may not be desirable. The configuration of springs only represents an alternative embodiment of the current invention; it will be further described in relation to a process for fabricating the springs directly on the back side of a semiconductor wafer.

The flexibility of finger 7 depends on its material properties and also on the ratio of length to width. The preferred material is copper which has desirable deformation properties; it deforms in a ductile manner, and can yield to applied forces over a wide range. A suitable range for length 8 is 50-250 μm and for diameter 9 is 5-25 μm while a length of 100 μm and diameter of 10 μm is preferred.

FIG. 1B shows a fragmentary view of the underside of Interface Adaptor 10 of FIG. 1A. A regular array 6 of fingers 7 is shown on base layer 5. Each finger has an end 11 and a bend 14.

FIG. 1C shows an alternative preferred embodiment of Interface Adaptor 10 that is labeled 10b. Interface Adaptor 10b has base layers 5b and 17, with an array 6 of fingers 7 extending between them. The primary application of this configuration is shock absorption. Providing the second base layer may also make it easier to manufacture the Interface Adaptor, and also may make attachment to a pair of interfacing objects easier. If protection against shock is required only in the −z direction, it may be desirable to unite all of the fingers in each row into a single element, including a bend 14 as shown in FIG. 1C. The structure having coalesced fingers will be capable of absorbing more impact energy than the structure having separated fingers.

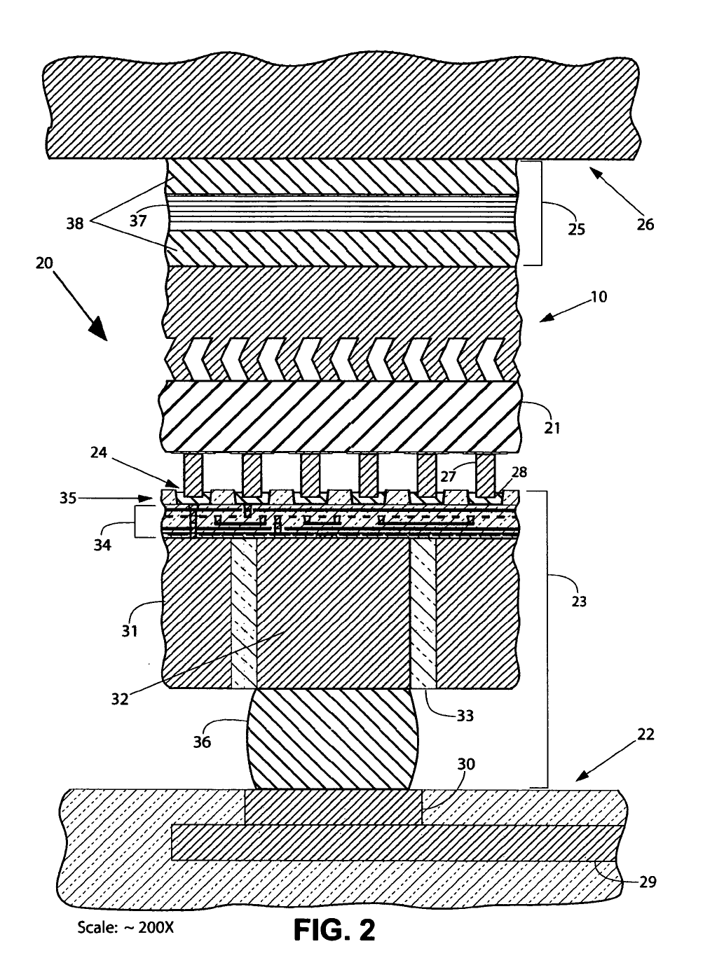

FIG. 2 shows a preferred stack 20 of electrical and thermal components surrounding a semiconductor chip 21, including a printed circuit board (PCB) 22, a copper-based ball grid array (BGA) substrate 23, MesaWell connectors 24 extending between chip 21 and BGA substrate 23, an Interface Adaptor 10 of the current invention, a stack of interfacing sheets 25, and a copper-based heat sink 26. The CTE of the copper-based components matches the CTE of the PCB (17 ppm/° C.). These are the thickest and strongest elements in the stack, and so they dominate the expansion characteristics in the −x and −y directions. The CTE of chip 21 is substantially different (3 ppm/° C.), and this is why compliant MesaWell connectors 24 are used at the bottom interface, and a compliant Interface Adaptor 10 is used at the top interface of chip 21. MesaWell connector 24 includes a plated copper mesa 27 that is flexible like a finger of an Interface Adaptor, and mesa 27 is also an electrical conduit that connects with a well filled with solder, 28. This arrangement provides mechanical compliance, good electrical performance, and re-workability of the flip chip connection. A related structure is described in U.S. patent application Ser. No. 10/701,888.

PCB 22 typically includes copper conductors 29 and a terminal in the form of a land 30 at each solder ball connection site. Copper-based BGA substrate 23 includes a copper substrate 31 with integrated feedthroughs 32, each feedthrough surrounded by an insulating cylinder 33. Built up on substrate 31 is a multi-layer high density interconnect (HDI) circuit 34, and fabricated on top of that is a special assembly layer 35 including wells filled with solder 28 for accepting copper mesa bumps 27. Solder ball attachment 36 connects between feedthrough 32 and land 30.

It may be convenient to attach Interface Adaptor 10 to IC chip 21 when chip 21 is in wafer form. This notion will be further developed in reference to FIG. 3. Interface adaptor 10 would then be built in a wafer form factor, attached after wafer processing, and diced along with the die.

Connection of heat sink 26 to Interface Adaptor 10 preferably uses a solder material for good thermal conductivity, and preferably does not require a reflow oven to melt the solder. A method for achieving this includes the use of an active foil layered with sheets of dry solder material. Thus, the stack of interfacing sheets 25 includes a reactive foil 37 layered between dry solder foils 38. The thermal, mechanical, and electrical connection is made by activating the exothermic reaction of reactive foil 37 (typically by creating a spark at the edge of the foil) and melting solder foils 38.

Interface Adaptor 10 may be fabricated as a buildup of printed layers, with each layer formed from printable inks. In this case, an ink is required for the positive copper shape and contains powdered copper particles in a binding material; the combination can be sintered to form a three-dimensional copper shape. Using this method, it is not difficult to create slanting structures such as are required to make fingers with a bend in them; each layer of the slanting member is patterned with a small offset from the previous layer, thus creating a “stair-case” geometry. A second ink is required for printing the negative space, not containing copper material. Prior to burning off the negative material that is providing support between the fingers, it is desirable to planarize the tips of the fingers using a chemical mechanical polishing (CMP) step.

FIG. 3 illustrates a schematic design of an electroplating cell 40 for electroforming the junction between an Interface Adaptor 10 and the backside of a semiconductor wafer 41. Cell 40 includes a base member 42 and a snap-on ring 43. The backside of wafer 41 is facing upwards and is coated with a seed layer of copper prior to placement in cell 40. Wafer 41 sits on a compliant layer 44 such as a sheet of foam, and an O-ring 45 is compressed as shown to provide a liquid seal at the periphery of wafer 41. The tips (ends) of the fingers of Interface Adaptor 10 are preferably in intimate contact with the copper-coated backside surface of wafer 41. Cell 40 is filled with plating solution 46 to a suitable level 47, encompassing plating electrode 48 which is typically fabricated from woven platinum wire. Preferably, plating solution 46 contains enough copper (without replenishment) to effectively plate the junctions between the tips of the fingers of Interface Adaptor 10 and the backside copper seed layer of semiconductor wafer 41. In this case, the required volume of plating solution is small, and it is discarded after each use. By electroforming these junctions a strong mechanical connection and a low-impedance thermal connection are provided between Interface Adaptor 10 and the backside of wafer 41. A second plating cycle may be employed to coat the copper with a thin protective layer of nickel. After the plating process is complete and the parts have been rinsed, wafer 41 is removed with the adaptor attached and the integrated assembly is preferably diced, rinsed, and dried. Bare copper surfaces may also be treated with an organic protective layer to prevent oxidation and contamination from handling. After dicing the wafer using a diamond saw, the singulated chips with attached adaptors are typically placed in carriers and kitted with other components, ready for package or board assembly.

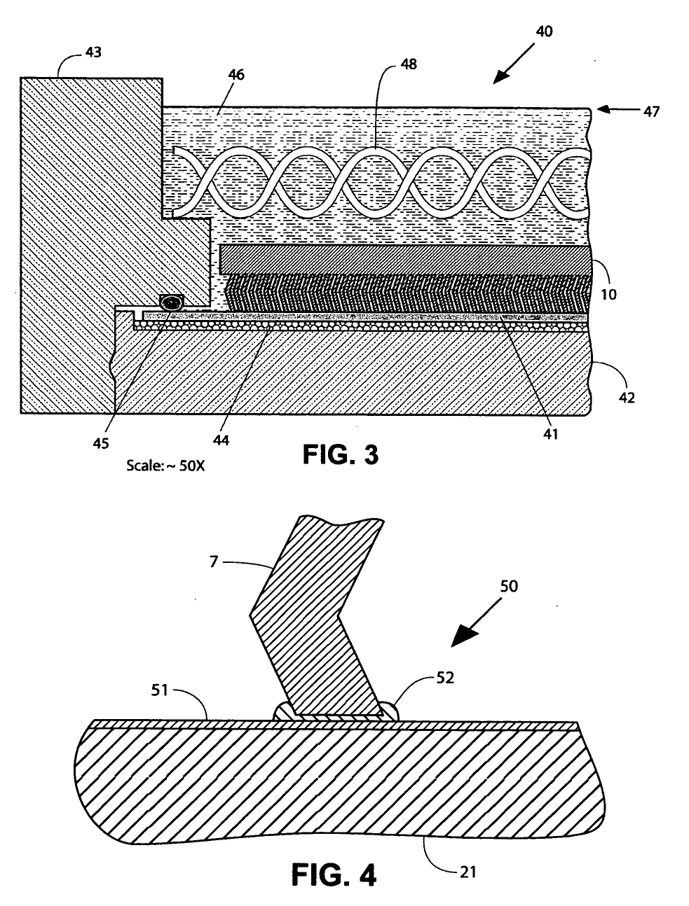

For relieving mechanical stresses only, the exposed ends of the fingers of the Interface Adaptor may be bonded to the corresponding mating surface using any bonding material having sufficient strength such as epoxy. However, if good thermal conductivity is also required, the bonding material should be selected from the most thermally conductive materials available. The use of plated copper as a bonding material was described in reference to FIG. 3; an alternative thermally conductive attachment 50 is described in FIG. 4. In this example, finger 7 is bonded to a solder-compatible coating 51 on the backside of wafer 21. Coating 51 may be sputtered copper for example. The ends of the fingers may be dipped in a solder paste and a solder flux before placing the Interface Adaptor on wafer 21. Heat is then applied to melt the solder 52 and create a thermally conductive joint 50 as shown.

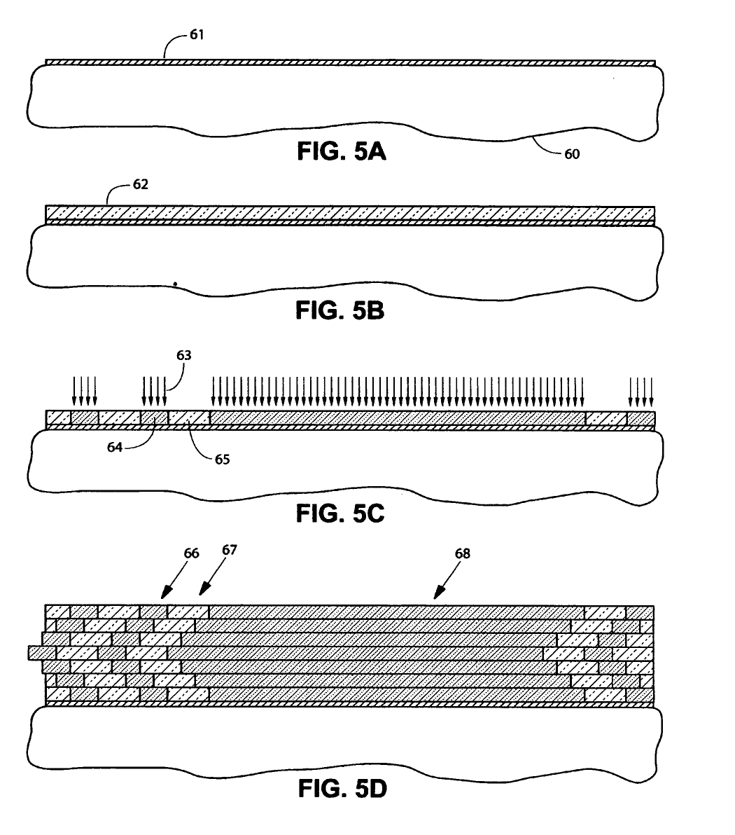

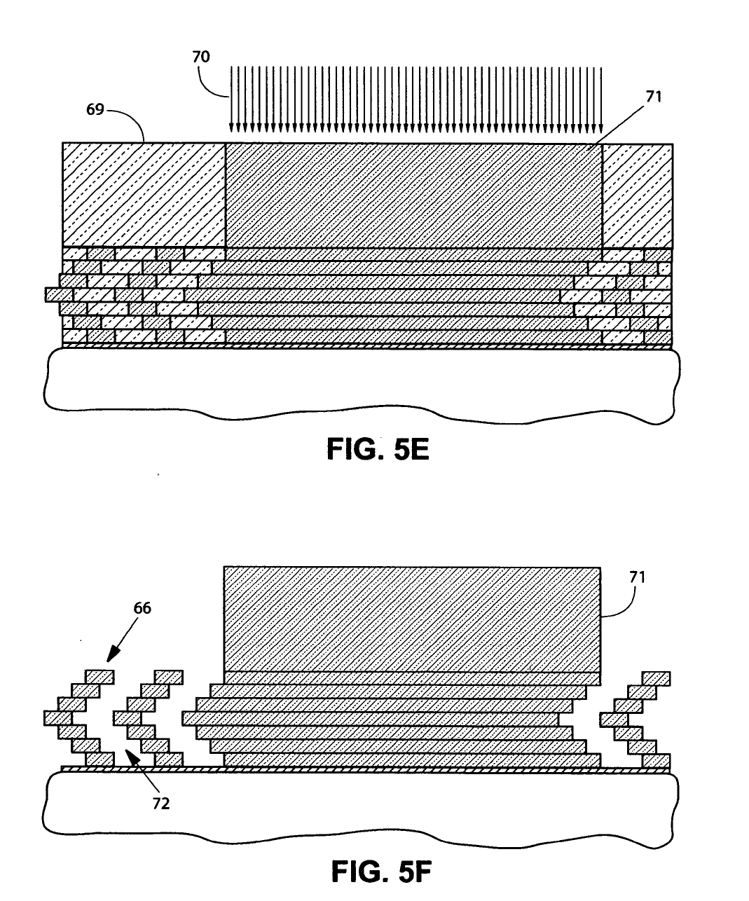

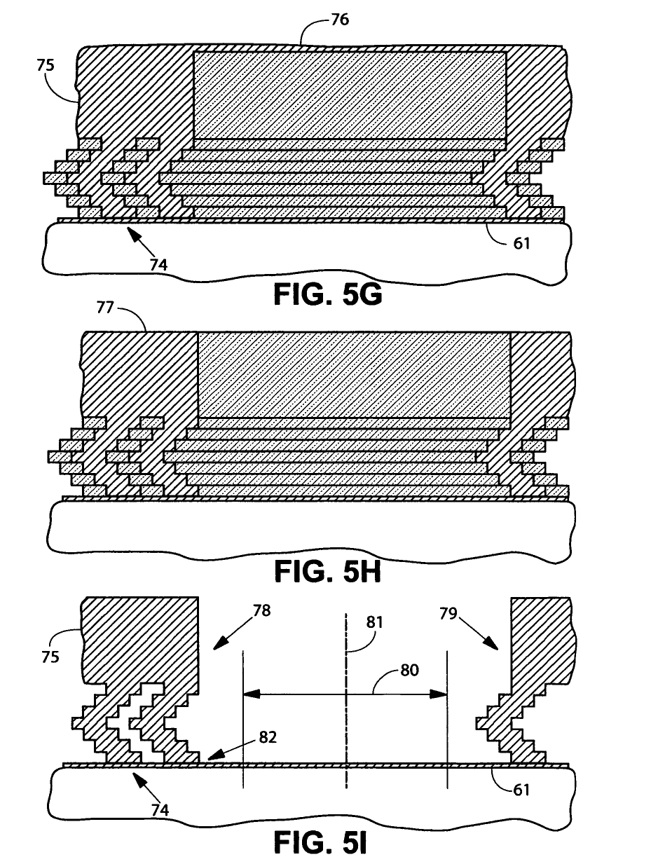

FIG. 5 depicts a sequence of process steps for directly fabricating Interface Adaptors on the back side of semiconductor wafers, using an additive copper process. FIG. 5A shows a fragment of a semiconductor wafer 60 whose back side has been coated with a seed layer 61 of copper. Wafer 60 may be silicon or any other semiconductor, and typically varies in diameter between 100 and 300 mm. In FIG. 5B the wafer has been spin-coated with a layer of negative photo resist 62, to a preferred thickness of 10-25 μm. FIG. 5C shows the exposure step wherein UV light 63 passes through a mask and illuminates the surface. The effect of the radiation is to cure the exposed portions by cross-linking the long chain polymer molecules of the resist. These exposed regions 64 are thereby cured, and will resist dissolution in developer. Neighboring regions 65 are unexposed and will subsequently be removed in developer.

The foregoing process of resist coating and exposure is repeated several times as shown in FIG. 5D, except that the mask is offset by a small distance between each exposure, thus creating a staircase pattern of exposed resist, 66. In the figure, a total of 7 layers form the staircase pattern; the mask offset between layers is reversed after the 4^{th} layer, to make a sideways V-shaped structure as shown. The adjacent staircase pattern 67 of unexposed resist will subsequently be occupied by electroformed copper, as will be further described, and the V-shape will implement a bent finger with the characteristics of a spring. A wide area of exposed resist 68 is provided at the scribe line between die to prevent copper formation in this area.

In FIG. 5E another layer of negative photo resist 69 is spin-coated as shown, with a preferred thickness of around 100 μm. Layer 69 is exposed by UV illumination 70 through another mask, with cross-linked region 71 corresponding to the scribe line area. Exposure dose 70 is higher than dose 63 of FIG. 5C to adequately expose the greater resist thickness. FIG. 5F shows the result of developing the resist, leaving exposed resist regions such as staircase pattern 66 and scribe blocking region 71. Although not shown in FIG. 5F, continuous webs of cured resist surround the vacated volumes such as 72, providing support.

FIG. 5G shows the result of electroplating up from seed layer 61, forming bent copper fingers 74, a copper base layer 75, and ending with an irregular surface 76. Layer 75 is referred to as the “base layer” even though it is not formed as the first electroplated layer, because it serves as the base support layer for the attached semiconductor component in typical applications. Irregular surface 76 becomes planarized surface 77 as shown in FIG. 5H after the wafer is polished using a CMP step, as is known in the art. FIG. 5I shows ends of Interface Adaptors, 78 and 79. They are spaced apart sufficiently that kerf width 80, centered on scribe line 81, is free of copper, thereby avoiding interference with the dicing operation. Copper finger 74 is shown and base layer 75. The connection 82 between finger 74 and seed copper layer 61 has low thermal impedance, comprising continuous copper with preferably no discernible junction between them.

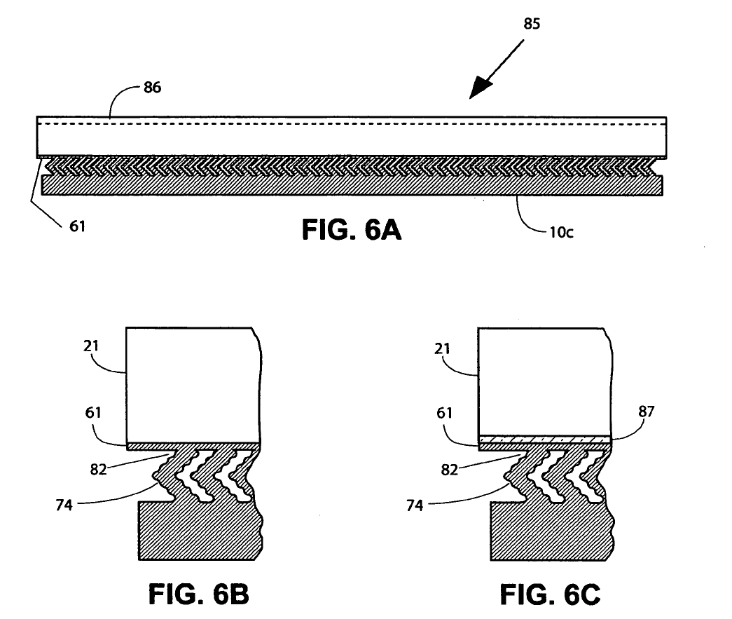

FIG. 6A shows a die 85 resulting from dicing a wafer that has been processed to produce integrated Interface Adaptors such as 10c. The active circuits on the wafer are fabricated in a thin layer 86 on the top side, and copper seed layer 61 is shown on the bottom or back side. A thermally conductive fluid may be injected into the space between fingers, preferably propagating by capillary action. The fluid will assist in lowering the thermal impedance at the interface.

FIG. 6B shows an expanded portion of FIG. 6A, showing detail of the preferred seamless joint 82 between copper finger 74 and copper seed layer 61.

FIG. 6C shows the inclusion of an electrical isolation layer 87 between semiconductor chip 21 and copper seed layer 61. Electrical isolation layer 87 may be required if the semiconductor substrate should not be grounded or connected to a power supply in the intended application. Also, since thermal grease is electrically insulating, for compatibility and ease of replacement it may be desirable for the Interface Adaptor to include an insulating layer. Any dielectric material can be used for layer 87; however the preferred material is silicon oxy-nitride, deposited using chemical vapor deposition (CVD). Layer 87 is preferably about 1 μm thick, and has only a small effect on the thermal impedance of the interface adaptor. The insulating layer could be provided at other locations within the stack; for example it could be provided between the Interface Adaptor and the heat sink. The essential requirement is that the insulating layer shall form an electrical barrier in series with one of the elements. However, for lowest cost using wafer level processing, and also for the smallest degradation in thermal impedance, the preferred isolation is provided as shown.

What is claimed is:

1. An adaptive interface component comprising:
one or more base layers; and,
an array of flexible fingers extending from said base layer.

2. The adaptive interface component of claim 1 wherein each of said fingers includes one or more bends.

3. The adaptive interface component of claim 1 fabricated from a thermally conductive material.

4. The adaptive interface component of claim 3 wherein said thermally conductive material is copper or an alloy of copper.

5. A thermal system comprising:
first and second elements having dissimilar expansion characteristics;
a thermal interface device interposed between said first and second elements;
said interface device having expansion characteristics similar to said first element;
said interface device including a conductive base and flexible conductive fingers extending therefrom;
a first attachment between said base and said first element; and,
a second attachment between the ends of said fingers and said second element.

6. The thermal system of claim 5 wherein said first element is a heat sink and said second element is a semiconductor die.

7. The thermal system of claim 5 wherein the junctions of said second attachment include material deposited from a plating solution.

8. The thermal system of claim 5 wherein the junctions of said second attachment include solder.

9. The thermal system of claim 5 and including a thin dielectric layer in series with one or more of said elements.

10. A thermal interface device comprising:
a base layer of heat-conductive material; and,
an array of flexible heat-conductive fingers extending from said base layer.

11. The thermal interface device of claim 10 wherein said base layer and said fingers are made of copper or an alloy of copper.

12. The thermal interface device of claim 10 wherein said fingers have a range in length of 50-250 μm and a range in diameter of 5-50 μm.

13. The thermal interface device of claim 12 wherein said fingers have a length of approximately 100 μm and a diameter of approximately 10 μm.

14. The thermal interface device of claim 10 and including a thermally conductive fluid or paste provided in the space between said fingers.

15. A method for mechanically interfacing between a first and a second object including the steps of:
a) providing an interface element including a base;
b) providing flexible fingers extending from said base;
c) attaching said base to said first object at a first common surface; and,
d) attaching the ends of said fingers to said second object at a second common surface.

16. A method for thermally coupling two objects including the steps of:
a) providing an interface element including a base having expansion characteristics similar to the first of said objects;
b) providing flexible fingers extending from said base;
c) attaching said base to said first object at a first common surface; and,
d) attaching the ends of said fingers to said second object at a second common surface.

17. The methods of claims 15 or 16 wherein said objects are laminates.

18. A monolithic shock absorber comprising:
a top and bottom base layer;
an array of bent fingers extending between said top and bottom base layers.

19. An interface adaptor integrated with a semiconductor chip comprising:
a semiconductor chip having a seed layer of copper on its back side;
an array of copper fingers that connect with said seed layer and extend in the direction normal to said chip; and,
a layer of copper that connects with the other end of said fingers to form a base.

20. The interface adaptor of claim 19 wherein said connections between copper elements are continuous with no seam or junction of dissimilar material.

21. The interface adaptor of claim 19 wherein said copper fingers have one or more bends in them.

22. The interface adaptor of claim 19 and including a dielectric or insulating layer between said semiconductor chip and said seed layer of copper.

23. A method for directly fabricating a set of interface springs on the back side of a semiconductor wafer comprising the steps of:
a) polishing said back side of said wafer if necessary to make it planar and smooth and free of oxide;
b) coating said back side with a seed layer of copper;
c) coating said seed layer with a negative photo resist;
d) exposing said resist through a mask to form cured regions;
e) repeating steps c and d multiple times, with a mask offset between each exposure to create a resist pattern wherein the unexposed portions are progressively defined as fingers having the form of staggered columns with a bend in the middle;
f) developing said resist to remove said uncured regions;
g) electroplating up from said seed layer to form copper fingers in said uncured regions;
h) polishing the ends of said fingers at the exposed surface if necessary; and,
i) stripping said cured resist regions if necessary to release said springs.

24. A method for directly fabricating a set of interface adaptors on the back side of a semiconductor wafer comprising the steps of:
a) polishing said back side of said wafer if necessary to make it planar and smooth and free of oxide;
b) coating said back side with a seed layer of copper;
c) coating said seed layer with a negative photo resist;
d) exposing said resist through a mask to form cured regions;
e) repeating steps c and d multiple times, with a mask offset between each exposure to create a resist pattern wherein the unexposed portions are progressively defined as fingers having the form of staggered columns with a bend in the middle;
f) coating with a thick layer of negative photo resist
g) exposing said thick layer through a mask to cure the regions at scribe lines;
h) developing said resist to remove said uncured regions;
i) electroplating up from said seed layer to form copper fingers in said uncured regions, followed by a copper base layer that connects with all of said fingers in each of said interface adaptors;
j) polishing said copper base layer at the exposed surface if necessary; and,
k) stripping said cured resist regions if necessary.
